(19) United States
(12) Patent Application Publication
(10) Pub. No.: US 2026/0223304 A1
(43) Pub. Date: Jul. 30, 2026

(54) Server Information Handling System Latch System

(71) Applicant: Dell Products L.P., Round Rock, TX (US)

(72) Inventors: Lawrence Ying-Hsi Lin, ZhongZheng DIstrict (TW); Chuan Chieh Tseng, Yonghe District (TW); Liu Sze Hao, Luzhou District (TW)

(21) Appl. No.: 19/038,000

(22) Filed: Jan. 27, 2025

(51) Int. Cl. H05K 5/02

(52) U.S. Cl. CPC H05K 5/0221

(57) ABSTRACT

A latch system of an information handling system. The latch system includes a handle component and a latching mechanism attached to the handle component, the latching mechanism performing an auto-lock operation between the information handling system and a rack when the information handling system is installed on the rack.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a server system with a latch system.

In one embodiment, the invention relates to a latch system of an information handling system, comprising: a handle component; and, a latching mechanism attached to the handle component, the latching mechanism performing an auto-lock operation between the information handling system and a rack when the information handling system is installed on the rack.

In another embodiment, the invention relates to a latching environment comprising: a rack; and, an information handling system chassis, the information handling system chassis including a latching system for attaching and removing the information handling system chassis to the rack, the latching system comprising a handle component; and, a latching mechanism attached to the handle component, the latching mechanism performing an auto-lock operation between the information handling system and the rack when the information handling system is installed on the rack.

In another embodiment, the invention relates to a system comprising: a chassis; and, a latch system mounted to the chassis, the latch system comprising a handle component; and, a latching mechanism attached to the handle component, the latching mechanism performing an auto-lock operation between the information handling system and a rack when the information handling system is installed on the rack.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIGS. 4A, 4B and 4C, generally referred to as FIG. 4, show views of a latch system in a locked orientation.

FIGS. 4D, 4E and 4F, generally referred to as FIG. 4, show views of a latch system in an unlocked orientation.

FIGS. 5A and 5B, generally referred to as FIG. 5, show views of a portion of a front of a server chassis.

### DETAILED DESCRIPTION

Various aspects of the present disclosure include an appreciation that it is known to provide information handling systems with a plurality of components. Various aspects of the present disclosure include an appreciation that information handling systems, such as server type information handing systems, include a plurality of components, can have increased weight when compared to previous information handling systems.

Various aspects of the present disclosure include an appreciation that it is known to provide server type information handling systems with a slam latch to secure the server information handling system to a server rack. Various aspects of the present disclosure include an appreciation that the slam latch can also prevent the server type information handling system from accidentally sliding out of the server rack. Various aspects of the present disclosure include an appreciation that with known information handling systems, the slam latch is also used as a handle when removing the information handling system chassis from the server rack. Various aspects of the present disclosure include an appreciation that for information handling systems which include a plurality of components, the slam latch can be too small for a user to hold and operate. Various aspects of the present disclosure include an appreciation that for information handling systems which include a plurality of components, extending the slam latch does not solve this issue as the slam latch is too slim and weak to perform its function effectively.

Various aspects of the present disclosure include an appreciation that it would be desirable to provide server type information handling systems with a large, solid, user-friendly handle component, especially as heavy systems like information handling systems designed to execute artificial intelligence and machine learning workloads become more prevalent.

A system and method are disclosed for providing an information handling system with a latch system. In certain embodiments, the latch system includes a handle component, a latching mechanism, a latch receptacle, or a combination thereof. In certain embodiments, the handle component is sized to facilitate manipulation of the information handling system. In certain embodiments, the handle component includes a frame element. In certain embodiments, the frame element is substantially D-shaped. In certain embodiments, the latching mechanism performs an auto-lock operation. In certain embodiments, the latching mechanism includes a trigger component and a locking component. In certain embodiments, the trigger component manipulates the locking component to release the locking component. In certain embodiments, the locking component interacts with the latch receptacle when performing the auto-lock operation. In certain embodiments, the locking component includes a latch projection receiving recess. In certain embodiments, the latch receptacle includes a latching projection. In certain embodiments, the latching projection interacts with the hook receiving recess when performing the auto-lock operation. In certain embodiments, the latching projection includes a hook shaped projection. In certain embodiments, the hook shaped projection extends from the chassis of the information handling system.

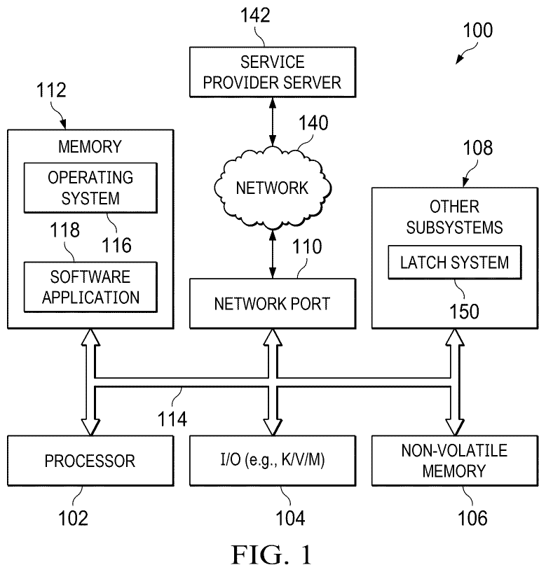

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, the other subsystems 108 include a latch system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the latch system 150 includes a handle component, a latching mechanism, a latch receptacle, or a combination thereof. In certain embodiments, the handle component is sized to facilitate manipulation of the information handling system. In certain embodiments, the handle component includes a frame element. In certain embodiments, the frame element is substantially D-shaped. In certain embodiments, the latching mechanism performs an auto-lock operation. As used herein, an auto-lock operation broadly refers to a function which attaches the information handling system to a server rack within needing separate fasteners when the information handling system is inserted into the server rack and which enable removal of the information handling system from the server rack without requiring removal of any separate fasteners. In certain embodiments, the latching mechanism includes a trigger component and a locking component. In certain embodiments, the trigger component manipulates the locking component to release the locking component. In certain embodiments, the locking component interacts with the latch receptacle when performing the auto-lock operation. In certain embodiments, the locking component includes a latch projection receiving recess. In certain embodiments, the latch receptacle includes a latching projection. In certain embodiments, the latching projection interacts with the hook receiving recess when performing the auto-lock operation. In certain embodiments, the latching projection includes a hook shaped projection. In certain embodiments, the hook shaped projection extends from the chassis of the information handling system.

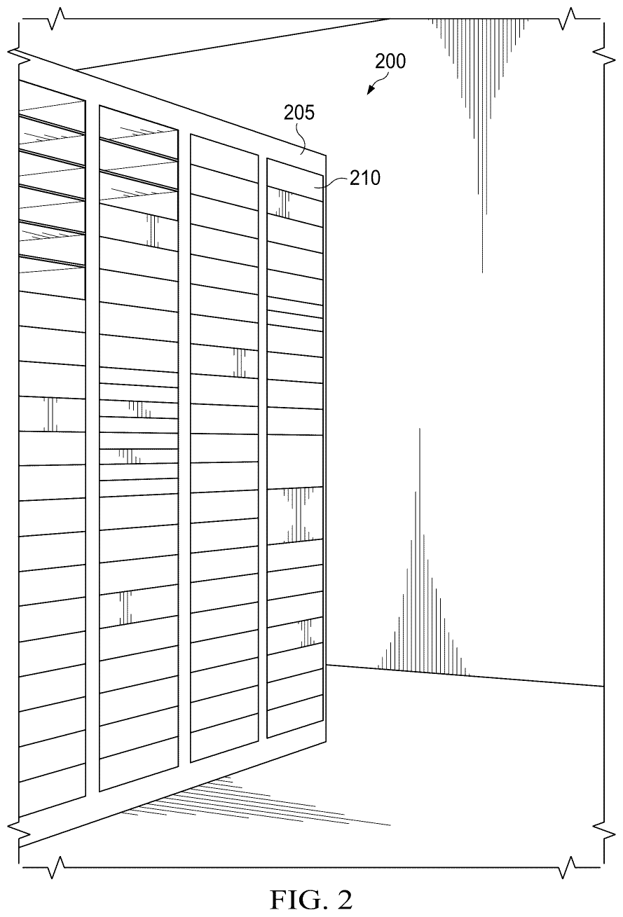

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100, as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit, and a 4U rack unit. In general, a 1U rack unit is substantially (i.e., +/−20%) 1.75″ high, a 2U rack unit is substantially (i.e., +/−20%) 3.5″ high, and a 4U rack height is substantially (i.e., +/−20%) 7.0″ high.

In certain embodiments, the rack and a chassis of an information handling system provide a latching environment. In certain embodiments, the chassis of the information handling system includes a latching system such as latching system 150 for attaching and removing the information handling system to the rack. In certain embodiments, the information handling system is attached and removed from the rack via an auto-lock operation.

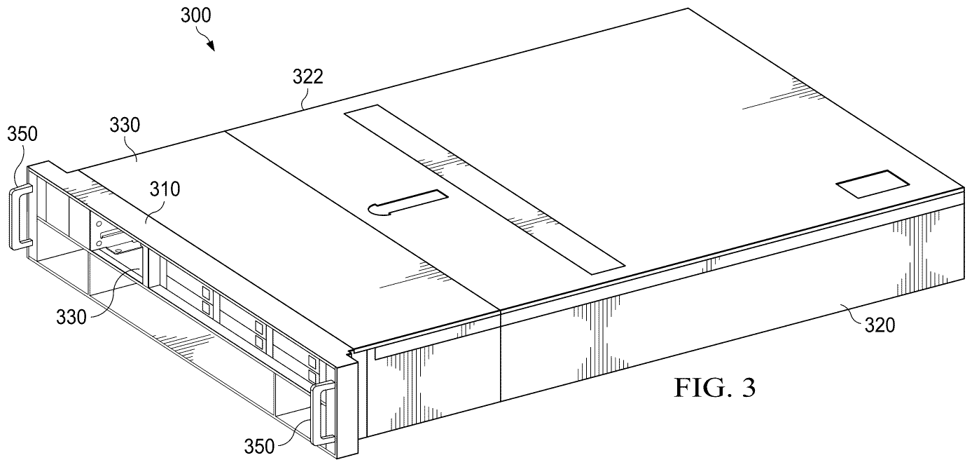

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the blade type information handing system 300 includes a bay 330 via which components may be mounted to the blade type information handling system. In certain embodiments, the information handling system 300 includes a latch system 350. In certain embodiments, the latch system 350 corresponds to latch system 150.

In certain embodiments, the latch system 350 includes a handle component, a latching mechanism, a latch receptacle, or a combination thereof. In certain embodiments, the handle component is sized to facilitate manipulation of the information handling system. In certain embodiments, the handle component includes a frame element. In certain embodiments, the frame element is substantially D-shaped. In certain embodiments, the latching mechanism performs an auto-lock operation. In certain embodiments, the latching mechanism includes a trigger component and a locking component. In certain embodiments, the trigger component manipulates the locking component to release the locking component. In certain embodiments, the locking component interacts with the latch receptacle when performing the auto-lock operation. In certain embodiments, the locking component includes a latch projection receiving recess. In certain embodiments, the latch receptacle includes a latching projection. In certain embodiments, the latching projection interacts with the hook receiving recess when performing the auto-lock operation. In certain embodiments, the latching projection includes a hook shaped projection. In certain embodiments, the hook shaped projection extends from the chassis of the information handling system.

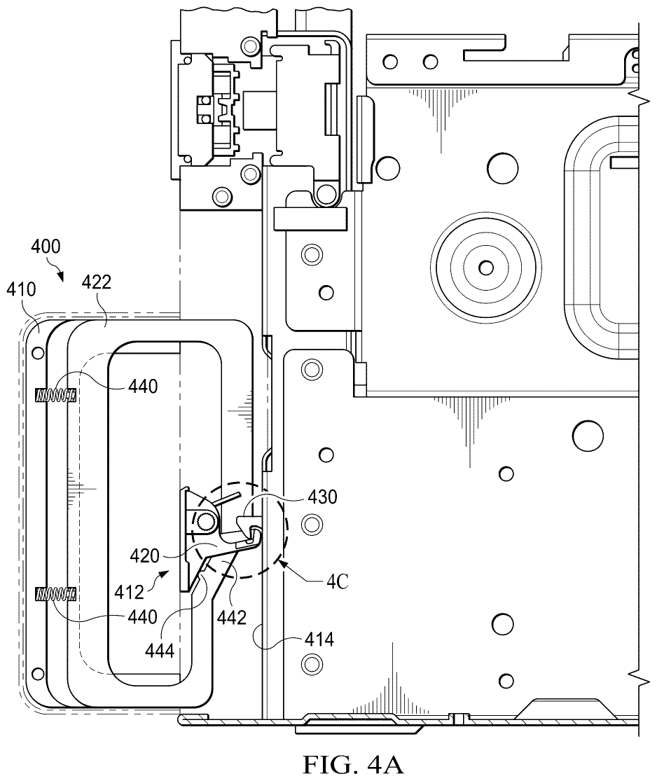

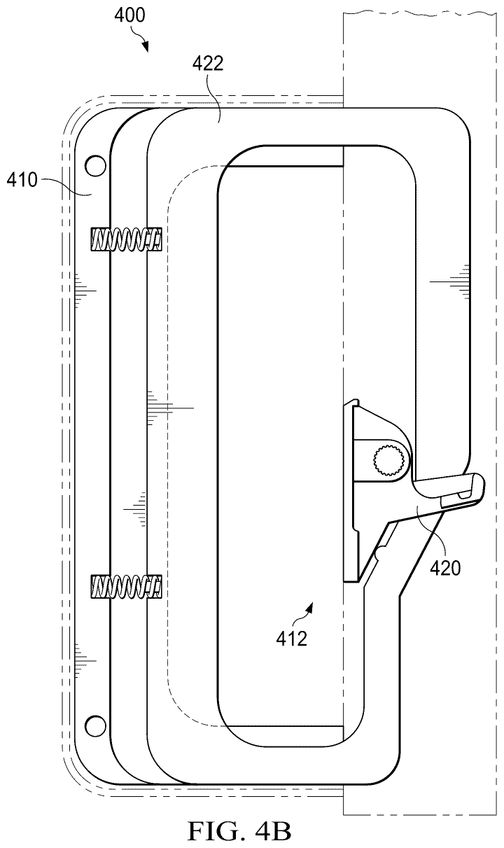

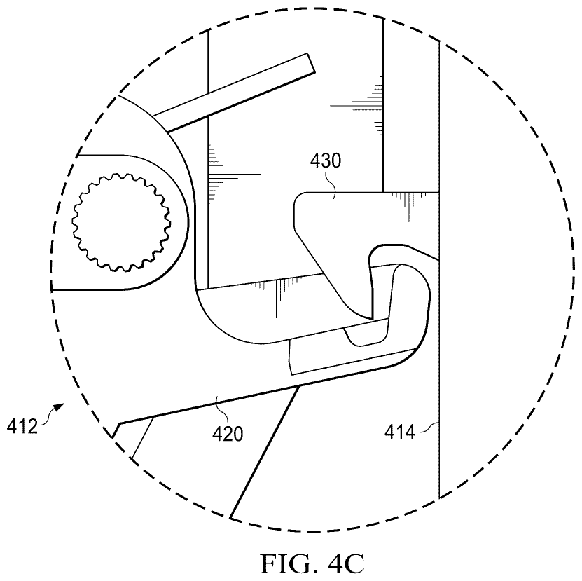

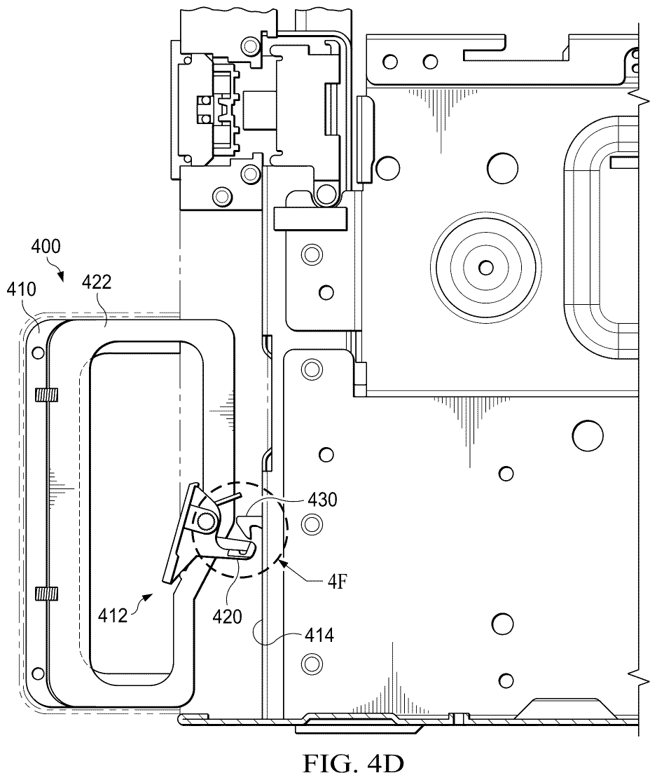

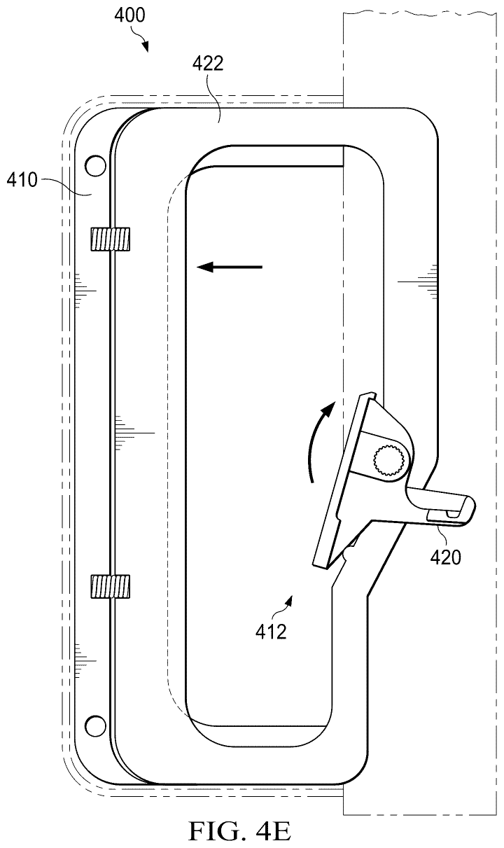

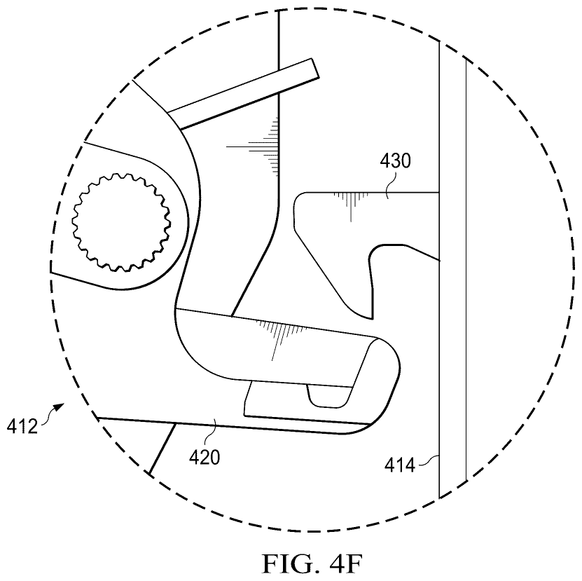

FIGS. 4A, 4B and 4C, generally referred to as FIG. 4, show views of a latch system 400 in a locked orientation. FIGS. 4D, 4E and 4F, generally referred to as FIG. 4, show views of the latch system 400 in an unlocked orientation. More specifically, FIG. 4A shows a side view of the latch system 400 interacting with a chassis of an information handling system when the latch system 400 is in a locked orientation. FIG. 4B shows a detailed side view of the latch system 400 when the latch system 400 is in a locked orientation. FIG. 4C shows a detailed side view of a portion of a trigger component of a latching mechanism, a locking component of the latching mechanism and a latching projection of a latch receptacle when the latch system 400 is in a locked orientation. FIG. 4D shows a side view of the latch system 400 interacting with a chassis of an information handling system when the latch system 400 is in an unlocked orientation. FIG. 4E shows a detailed side view of the latch system 400 when the latch system 400 is in an unlocked orientation. FIG. 4F shows a detailed side view of a portion of a trigger component of a latching mechanism, a locking component of the latching mechanism and a latching projection of a latch receptacle when the latch system 400 is in an unlocked orientation.

In certain embodiments, the latch system 400 includes a handle component 410, a latching mechanism 412, a latch receptacle 414, or a combination thereof. In certain embodiments, the handle component 410 is sized to facilitate manipulation of the information handling system. In certain embodiments, the handle component 410 includes a frame element. In certain embodiments, the frame element is substantially D-shaped.

In certain embodiments, the latching mechanism 412 performs an auto-lock operation. In certain embodiments, the latching mechanism 412 includes a locking component 420 and trigger component 422. In certain embodiments, the locking component 420 is configured as a slam latch. In certain embodiments, the trigger component 422 manipulates the locking component 420 to release the locking component. In certain embodiments, the locking component 420 interacts with the latch receptacle 430 when performing the auto-lock operation. In certain embodiments, the locking component 420 includes a latch projection receiving recess.

In certain embodiments, the latch receptacle 414 includes a latching projection 430. In certain embodiments, the latching projection 430 interacts with the latch projection receiving recess when performing the auto-lock operation. In certain embodiments, the latching projection 430 includes a hook shaped projection. In certain embodiments, the hook shaped projection extends from the chassis of the information handling system.

In certain embodiments, the trigger component 422 is slidably attached to the handle component 410. In certain embodiments, one or more force generating elements 440 are attached between the trigger component 422 and the handle component 410. In certain embodiments, the force generating elements 440 include respective springs. In certain embodiments, the one or more force generating elements 440 apply a force against the trigger component 422 to keep the trigger component in a trigger component locked orientation.

In certain embodiments, the trigger component 422 includes a sloped portion 442. In certain embodiments, the sloped portion 442 is located on an inside edge of the trigger component 422. In certain embodiments, the sloped portion 442 interacts with the locking component 420. In certain embodiments, the sloped portion 442 interacts with the locking component 420 when the trigger component 420 is actuated to move the trigger component 420 between the trigger component locked orientation and a trigger component unlocked orientation. In certain embodiments, when the trigger component 420 moves to the trigger component unlocked orientation, the sloped portion 442 applies a force against the locking component 420 to cause the locking component to move from a locking component locked orientation to a locking component unlocked orientation. In certain embodiments, the locking component 420 rotates when moving from the locking component locked orientation to the locking component unlocked orientation. When the locking component 420 rotates to the locking component unlocked orientation, the latching projection 430 is released, allowing the information handling system chassis to be pulled from server rack. When the locking component 420 rotates to the locking component locked orientation, the locking component 420 engages the latching projection 430, the information handling system chassis is physically attached to the server rack without requiring any additional fastening hardware.

In certain embodiments, the sloped portion 442 includes a trigger projection 444. In certain embodiments, the trigger projection 444 interacts with the locking component 420. In certain embodiments, the trigger projection 444 interacts with the locking component 420 when the trigger component 422 is actuated to move the trigger component 422 between the trigger component locked orientation and a trigger component unlocked orientation.

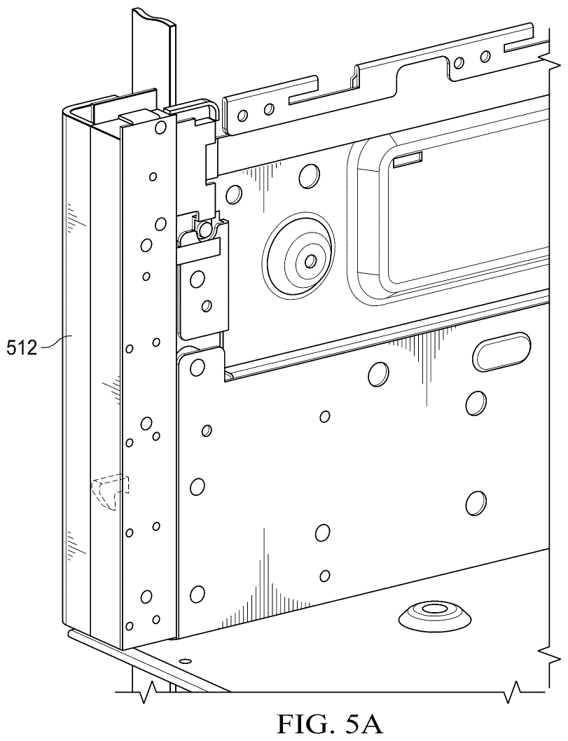

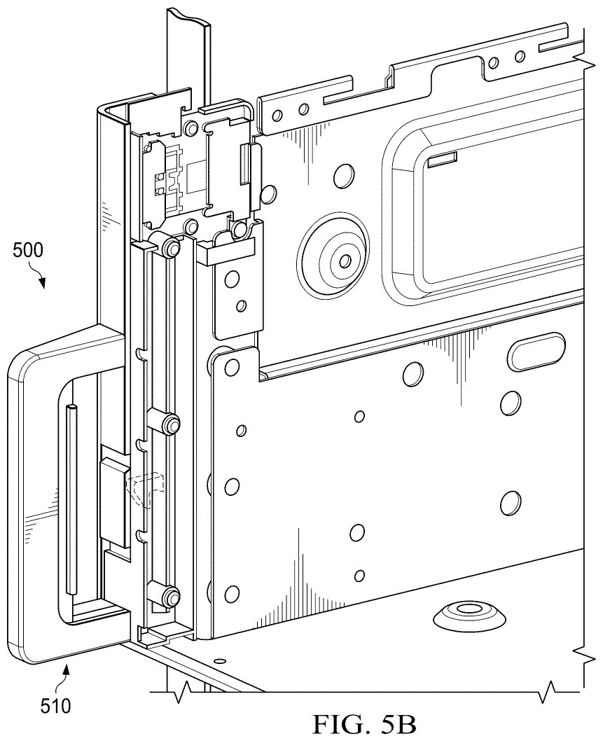

FIGS. 5A and 5B, generally referred to as FIG. 5, show views of a portion of a front of a server chassis. More specifically, FIG. 5A shows a front perspective view of a portion of a front of a server chassis without a latch system 510 attached to a latch receptacle 512. FIG. 5B shows a front perspective view of a portion of a server chassis with a latch system 510 installed and attached to the latch receptacle 512. In certain embodiments, the latch system 510 corresponds to latch system 150. In certain embodiments, the latch system 510 is configured to interact with latch receptacle 512. In certain embodiments, the latch receptacle 512 is physically attached to a server rack to which the information handling system is mounted.

In certain embodiments, the latch system 510 includes a handle element 520 which is physically attached to a latch housing component 522. In certain embodiments, the latch housing component 522 extends vertically along an edge of the information handling system chassis.

In certain embodiments, the handle element 520 defines a channel into which a trigger component 524 fits. In certain embodiments, the channel extends along interior edges of the handle element 520. In certain embodiments, the channel extends along a top interior edge of the handle element 520, a front interior edge of the handle element 520, a bottom interior edge of the handle element 520, or a combination thereof. In certain embodiments, the latch housing component 522 defines apertures via which the trigger component 524 extends within a front edge of the latch housing component 522 such that a locking component of the latch system 510 can interact with the latch receptacle 512.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A latch system of an information handling system, comprising:
a handle component; and,
a latching mechanism attached to the handle component, the latching mechanism performing an auto-lock operation between the information handling system and a rack when the information handling system is installed on the rack.

2. The latch system of claim 1, wherein:
the latching mechanism includes a trigger component and a locking component, the trigger component manipulating the locking component.

3. The latch system of claim 2, wherein:
the trigger component rotates the locking component between a locking component locked orientation and a locking component unlocked orientation.

4. The latch system of claim 3, wherein:
the locking component interacts with a latch receptacle when performing the auto-lock operation.

5. The latch system of claim 2, wherein:
the trigger component includes a sloped portion; and
the sloped portion interacts with the locking component when the trigger component manipulates the locking component.

6. The latch system of claim 1, wherein:
the handle component defines a channel; and,
the latching mechanism fits within the channel.

7. A latching environment comprising:
a rack; and,
an information handling system chassis, the information handling system chassis including a latching system for attaching and removing the information handling system chassis to the rack, the latching system comprising
a handle component; and,
a latching mechanism attached to the handle component, the latching mechanism performing an auto-lock operation between the information handling system and the rack when the information handling system is installed on the rack.

8. The latching environment of claim 7, wherein:
the latching mechanism includes a trigger component and a locking component, the trigger component manipulating the locking component.

9. The latching environment of claim 8, wherein:
the trigger component rotates the locking component between a locking component locked orientation and a locking component unlocked orientation.

10. The latching environment of claim 9, wherein:
the locking component interacts with a latch receptacle when performing the auto-lock operation.

11. The latching environment of claim 8, wherein:
the trigger component includes a sloped portion; and
the sloped portion interacts with the locking component when the trigger component manipulates the locking component.

12. The latching environment of claim 7, wherein:
the handle component defines a channel; and,
the latching mechanism fits within the channel.

13. A system comprising:
a chassis;
a latch system mounted to the chassis, the latch system comprising
a handle component; and,
a latching mechanism attached to the handle component, the latching mechanism performing an auto-lock operation between the information handling system and a rack when the information handling system is installed on the rack.

14. The system of claim 13, wherein:
the latching mechanism includes a trigger component and a locking component, the trigger component manipulating the locking component.

15. The system of claim 14, wherein:
the trigger component rotates the locking component between a locking component locked orientation and a locking component unlocked orientation.

16. The system of claim 15, wherein:
the locking component interacts with a latch receptacle when performing the auto-lock operation.

17. The system of claim 14, wherein:
the trigger component includes a sloped portion; and
the sloped portion interacts with the locking component when the trigger component manipulates the locking component.

18. The system of claim 13, wherein:
the handle component defines a channel; and,
the latching mechanism fits within the channel.
